(19) United States
(12) Patent Application Publication
(10) Pub. No.: US 2016/0343547 A1
(43) Pub. Date: Nov. 24, 2016

(54) SUBSTRATE-PROCESSING SYSTEM AND METHOD OF COATING CARBON-PROTECTION LAYER THEREFOR

(71) Applicant: Samsung Electronics Co., Ltd., Suwon-si (KR)

(72) Inventors: Seungkyu LIM, Hwasung-City (KR); Myoung Soo PARK, Hwasung-City (KR); Dougyong SUNG, Hwasung-City (KR)

(73) Assignee: Samsung Electronics Co., Ltd., Suwon-si (KR)

(21) Appl. No.: 15/148,440

(22) Filed: May 6, 2016

(30) Foreign Application Priority Data
May 20, 2015 (KR) 10-2015-0070622

(51) Int. Cl. H01J 37/32; C23C 16/455; C23C 16/27; C23C 16/50; H01L 21/683; H01L 21/67

(52) U.S. Cl. CPC H01J 37/32642; H01L 21/6831; H01L 21/67069; H01J 37/32009; C23C 16/27; C23C 16/50; H01J 37/3244; C23C 16/455; H01J 2237/334; H01J 2237/332

(57) ABSTRACT

Provided is a substrate processing system including a plasma processing module and a protection layer coated on the plasma processing module. The protection layer may include a diamond film.

### CROSS-REFERENCE TO RELATED APPLICATION

This application claims priority from Korean Patent Application No. 10-2015-0070622, filed on May 20, 2015, in the Korean Intellectual Property Office, the disclosure of which is incorporated herein by reference in its entirety.

### BACKGROUND

Methods and apparatuses consistent with exemplary embodiments relate to a substrate processing system, and in particular, to a substrate processing system of etching a substrate using plasma reaction and a method of coating a carbon protection layer therefor.

In the related art, semiconductor devices may be manufactured using a plurality of unit processes, such as a thin-film deposition process, a diffusion process, a thermal treatment process, a photolithography process, a polishing process, an etching process, an ion implantation process, and a cleaning process. Some of the above-discussed processes (e.g., the etching process) may be performed based on plasma reaction. By using the plasma reaction, it is possible to enhance the straightness of the reaction gas in the etching process. However, the plasma reaction may lead to a reduction in the lifespan of a plasma processing module.

### SUMMARY

One or more exemplary embodiments provide a substrate processing system, allowing a plasma processing module to have an increased lifespan, and a method of coating a carbon protection layer therefor.

One or more exemplary embodiments also provide a substrate processing system capable of suppressing occurrence of particles and a method of coating a carbon protection layer therefor.

According to an aspect of an exemplary embodiment, a substrate processing system may include a plasma processing module, and a carbon protection layer coated on the plasma processing module. The carbon protection layer may include a first diamond film.

According to an aspect of an exemplary embodiment, a method of coating a carbon protection layer may include providing a plasma processing module and forming a carbon protection layer on the plasma processing module. The forming of the carbon protection layer may include forming a first diamond film.

According to an aspect of another exemplary embodiment, a substrate processing system may include an upper housing, a lower housing below the upper housing, and a carbon protection layer coated on an inner surface of the lower housing. The carbon protection layer may include a first diamond film.

According to an aspect of another exemplary embodiment, a substrate processing system may include a chamber including a lower housing and an upper housing on the lower housing and a carbon protection layer coated on an inner surface of the lower housing. The carbon protection layer may include a first diamond film.

According to an aspect of another exemplary embodiment, there is provided a substrate processing system including: a plasma processing module; and a protection layer coated on the plasma processing module, wherein the protection layer includes a first diamond film.

The plasma processing module may include: an electrostatic chuck configured to fasten a substrate; and an edge ring including: a focus ring provided at an edge of the substrate; and a cover ring enclosing the focus ring, wherein the first diamond film is provided on the focus ring.

The focus ring may include silicon carbide, and the first diamond film may have a (111) crystal plane.

The first diamond film may include: micro-crystalline diamonds; or nano-crystalline diamonds having a smaller size than a size of the micro-crystalline diamonds.

The first diamond film may further include graphite that is mixed with the micro-crystalline diamonds or the nano-crystalline diamonds.

Each of the micro- and nano-crystalline diamonds may be provided to have a mixing ratio of 85% or higher in the first diamond film with respect to graphite.

The protection layer may further include a first graphene film disposed between the plasma processing module and the first diamond film.

The protection layer may further include: a second graphene film provided on the first diamond film; and a second diamond film provided on the second graphene film.

The protection layer may further include a carbyne film on the second diamond film.

The plasma processing module may include a chamber, and the protection layer may be coated on an inner surface of the chamber.

According to an aspect of another exemplary embodiment, there is provided a method of coating a protection layer including: providing a plasma processing module; and forming the protection layer on the plasma processing module, wherein the forming the protection layer may include forming a first diamond film on the plasma processing module.

The forming the first diamond film may include forming the first diamond film under a pressure of about 10,000 atm to 100,000 atm and at a temperature of about 800° C. by a chemical vapor deposition process.

The forming the protection layer may further include providing a first graphene film between the plasma processing module and the first diamond film, and the first graphene film may be formed at a temperature of about 1500° C. by a chemical vapor deposition process.

The forming the protection layer may further include providing a carbyne film on the first diamond film, and the carbyne film may be formed under a pressure of about 1,000,000 atm or higher by a chemical vapor deposition process.

The providing the plasma processing module may include performing a texturing process on a surface of the plasma processing module.

According to an aspect of another exemplary embodiment, there is provided a substrate processing system including: an upper housing; a lower housing below the upper housing; and a protection layer coated on an inner surface of the lower housing, wherein the protection layer includes a first diamond film.

The lower housing may include: a wall liner; an electrostatic chuck provided in the wall liner and configured to fasten a substrate; and a first ring provided at an edge of the substrate, the first ring containing silicon carbide, wherein the first diamond film has a (111) crystal plane.

The protection layer may further include a first graphene film provided on the first ring and the first diamond film.

The protection layer may further include: a second graphene film provided on the first diamond film; and a second diamond film provided on the second graphene film.

The protection layer may further include a carbyne film provided on the second diamond film.

According to an aspect of another exemplary embodiment, there is provided a substrate processing system including: a chamber including: a lower housing; and an upper housing provided on the lower housing; and a protection layer coated on an inner surface of the lower housing, wherein the protection layer includes a first diamond film.

The lower housing may include: an electrostatic chuck configured to fasten a substrate; and a ring member including: an edge ring enclosing an edge of the substrate; and a ground ring enclosing the electrostatic chuck under the edge ring, wherein the first diamond film is coated on the edge ring.

The edge ring may include: a first ring provided at the edge of the substrate; and a second ring enclosing the first ring, wherein the first diamond film is coated on the first ring.

The first diamond film may be coated from the first ring to the ground ring via the second ring.

The first ring may include silicon carbide, and the first diamond film has a (111) crystal plane.

The upper housing may include a shower head provided over the lower housing, and the first diamond film is coated on the shower head.

The first diamond film may include: micro-crystalline diamonds; or nano-crystalline diamonds having a smaller size than a size of the micro-crystalline diamonds.

The first diamond film may further include graphite that is mixed with the micro-crystalline diamonds or the nano-crystalline diamonds.

Each of the micro- and nano-crystalline diamonds may be provided to have a mixing ratio of 85% or higher in the first diamond film with respect to graphite.

The protection layer may further include a first graphene film disposed between the plasma processing module and the first diamond film.

The protection layer may further include: a second graphene film provided on the first diamond film; and a second diamond film provided on the second graphene film.

The protection layer may further include a carbyne film provide on the second diamond film.

According to an aspect of another exemplary embodiment, there is provided a substrate processing apparatus, including: a processing chamber configured to process a substrate using reaction gas; and a protection layer configured to protect the processing chamber from the reaction gas supplied into the processing chamber, wherein the protection layer includes a first diamond film.

The processing chamber may include: a lower housing; and an upper housing detachably attached to the lower housing, wherein the first diamond film is coated on an inner surface of the lower housing.

The first diamond film may be coated on an inner surface of the upper housing.

The first diamond film may include micro-crystalline diamonds (MCD) or nano-crystalline diamonds (NCD) and a particle size of the MCD may be larger than a particle size of the NCD.

The first diamond film may further include graphite that is mixed with the MCD or the NCD.

Each of the MCD and NCD may be provided to have a mixing ratio of 85% or higher in the first diamond film with respect to the graphite.

The particle size of MCD may be in a range between about 1 μm and about 15 μm, and the particle size of NCD may be in a range between about 10 nm and about 100 nm.

The protection layer may further include a first graphene film disposed between the processing chamber and the first diamond film.

The protection layer may further include: a second diamond film provided on the first diamond film; and a second graphene film disposed between the first diamond film and the second diamond film.

### BRIEF DESCRIPTION OF THE DRAWINGS

Exemplary embodiments will be more clearly understood from the following brief description taken in conjunction with the accompanying drawings. The accompanying drawings represent non-limiting, exemplary embodiment as described herein.

FIG. 1 is a sectional view illustrating a substrate processing system according to an exemplary embodiment t.

FIG. 2 is an exploded sectional view illustrating the chamber of FIG. 1.

FIG. 3 is a sectional view illustrating a ring member and a plasma protection layer of FIG. 1 according to an exemplary embodiment.

FIG. 4 is a sectional view illustrating an exemplary embodiment of the focus ring and the plasma protection layer that are provided in a portion A of FIG. 3.

FIG. 5 is a graph showing XRD curves of the focus ring and the first diamond film of FIG. 4 according to an exemplary embodiment.

FIGS. 6A and 6B are plan views illustrating the first diamond film of FIG. 4 according to an exemplary embodiment.

FIG. 7A is a graph illustrating Raman spectrum of the micro-crystalline diamonds (MCD) of FIG. 6A according to an exemplary embodiment.

FIG. 7B is a graph illustrating Raman spectrum of the nano-crystalline diamonds (NCD) of FIG. 6B according to an exemplary embodiment.

FIG. 8A is a graph showing an etching depth of a first diamond film against a mixing ratio of the MCD in the first diamond film of FIG. 6A according to an exemplary embodiment.

FIG. 8B is a graph showing an etching depth of a first diamond film against a mixing ratio of the NCD in the first diamond film of FIG. 6B according to an exemplary embodiment.

FIG. 9 is a graph showing the etch rate for each of MCD, NCD (shown in FIGS. 6A and 6B), silicon, and silicon carbide.

FIG. 10 is a flow chart illustrating a method of forming a plasma protection layer of a substrate processing system according to an exemplary embodiment.

FIG. 11 is a sectional view illustrating an exemplary embodiment of the plasma protection layer of FIG. 4.

FIG. 12 is a flow chart illustrating a method of forming a plasma protection layer of FIG. 11 according to an exemplary embodiment.

FIG. 13 is a sectional view illustrating an exemplary embodiment of the plasma protection layer of FIG. 4.

FIG. 14 is a flow chart illustrating a method of forming the plasma protection layer of FIG. 13.

FIG. 15 is a sectional view illustrating an exemplary embodiment of the plasma protection layer of FIG. 4.

FIG. 16 is a flow chart illustrating a method of forming the plasma protection layer of FIG. 15.

FIG. 17 is a sectional view illustrating an exemplary embodiment of the substrate processing system of FIG. 1.

FIG. 18 is an exploded sectional view illustrating the chamber of FIG. 17.

FIG. 19 is a sectional view illustrating a ring member of FIG. 17.

It should be noted that the above-described figures are intended to illustrate the general characteristics of methods, structure and/or materials utilized in certain exemplary embodiment and to supplement the written description provided below. The figures are not drawn, however, to scale and may not precisely reflect the structural or performance characteristics of any given embodiment, and should not be interpreted as defining or limiting the range of values or properties encompassed by exemplary embodiment. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Exemplary embodiments will now be described more fully with reference to the accompanying drawings. The exemplary embodiments of the inventive concepts may, however, be embodied in many different forms and should not be construed as being limited to the exemplary embodiments set forth herein; rather, the exemplary embodiments are provided so that this disclosure will be thorough and complete, and will fully convey the concept of exemplary embodiment to those of ordinary skill in the art. In the drawings, the thicknesses of layers and regions are exaggerated for clarity. Like reference numerals in the drawings denote like elements, and thus their description will be omitted.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of exemplary embodiment.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the exemplary embodiment. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which exemplary embodiment of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

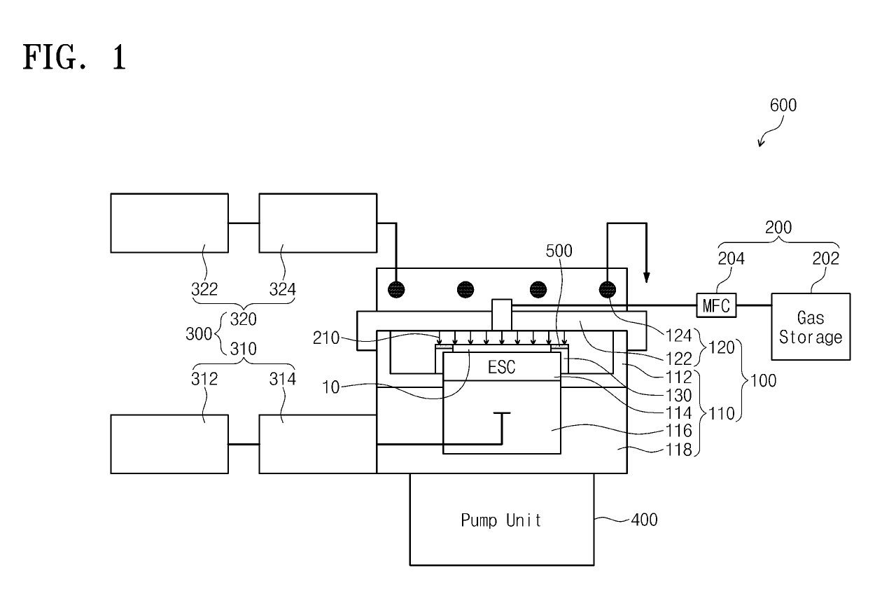

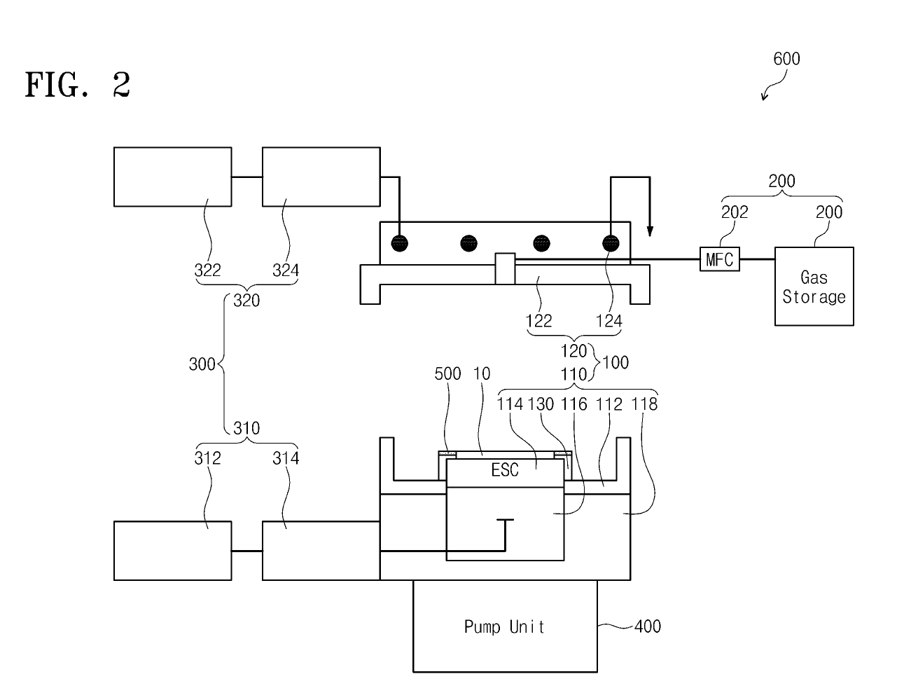

FIG. 1 is a diagram illustrating a substrate processing system according to an exemplary embodiment. FIG. 2 is an exploded sectional view illustrating a chamber of FIG. 1.

Referring to FIGS. 1 and 2, a substrate processing system 600 may be a reactive plasma etching system or an inductively-coupled plasma etching system. In an exemplary embodiment, the substrate processing system 600 may include a chamber 100, a gas supplying unit 200, a high frequency power supply unit 300, a pumping unit 400, and a plasma protection layer 500. The chamber 100 may be configured to perform a specific process on a substrate 10. For example, the specific process may be a dry etching process. Alternatively, the specific process may be a chemical vapor deposition process or a sputtering process. The gas supplying unit 200 may be configured to supply a reaction gas 210 into the chamber 100. The reaction gas 210 may be a strongly acidic etching gas (e.g., SF₆, HF, or CF₄). The high frequency power supply unit 300 may be configured to apply a high frequency power to the chamber 100. The high frequency power may be used to induce plasma reaction of the reaction gas 210. The pumping unit 400 may be configured to pump out the reaction gas 210 from the chamber 100. The plasma protection layer 500 may be provided in the chamber 100.

The chamber 100 may be a module configured to process the substrate 10 using plasma. In an exemplary embodiment, the chamber 100 may include a lower housing 110 and an upper housing 120. The substrate 10 may be disposed on the lower housing 110. The upper housing 120 may be provided on the substrate 10. The lower housing 110 and the upper housing 120 may be separated from each other, when the substrate 10 is loaded in the chamber 100.

The lower housing 110 may be configured to upwardly or downwardly move with respect to the upper housing 120. For example, the lower housing 110 may include a wall liner 112, an electrostatic chuck 114, a ring member 130, a lower electrode 116, and a supporting block 118. The wall liner 112 may be coupled with the upper housing 120. The electrostatic chuck 114 may be disposed in the wall liner 112. The electrostatic chuck 114 may be configured to fasten the substrate 10 using an electrostatic force. The reaction gas 210 may be supplied into a space between the substrate 10 and the upper housing 120. The ring member 130 may be disposed at an edge of the substrate 10. Alternatively, the ring member 130 may be provided to surround a sidewall of the electrostatic chuck 114. The lower electrode 116 may be provided below the electrostatic chuck 114. The supporting block 118 may support the wall liner 112 and the lower electrode 116. Although not shown, a lifter may be provided to allow the supporting block 118 to be moved in a vertical direction.

The upper housing 120 may be provided on the lower housing 110. The upper housing 120 may include, for example, a shower head 122 and an upper electrode 124. The shower head 122 may be provided over the substrate 10 and the electrostatic chuck 114. The shower head 122 may supply the reaction gas 210 onto the substrate 10. The upper electrode 124 may be provided on the shower head 122. The upper electrode 124 may be used to induce a plasma reaction of the reaction gas 210 using a high frequency power.

The pumping unit 400 may be provided below the lower housing 110. The pumping unit 400 may be used to exhaust the reaction gas to the outside of the chamber, after the specific process. The pumping unit 400 may include, for example, a vacuum pump.

The gas supplying unit 200 may be connected to the upper housing 120. In an exemplary embodiment, the gas supplying unit 200 may include a gas storage 202 and a mass flow control valve 204. The gas storage 202 may be configured to store the reaction gas 210. The mass flow control valve 204 may be provided on a conduit connecting the gas storage 202 to the upper housing 120. The mass flow control valve 204 may be used to adjust a flow rate of the reaction gas to be supplied into the chamber 100.

The high frequency power supply unit 300 may be configured to apply a high frequency power to the lower electrode 116 and the upper electrode 124. The high frequency power supply unit 300 may include, for example, a first high frequency power supply unit 310 and a second high frequency power supply unit 320. The first high frequency power supply unit 310 may be connected to the lower electrode 116. The second high frequency power supply unit 320 may be connected to the upper electrode 124. The first high frequency power supply unit 310 may include, for example, a first high frequency generator 312 and a first matcher 314. The first high frequency generator 312 may be configured to generate a first high frequency power. The first matcher 314 may be connected between the first high frequency generator 312 and the lower electrode 116. The first matcher 314 may be used for impedance matching of the first high frequency power. The second high frequency power supply unit 320 may include a second high frequency generator 322 and a second matcher 324. The second high frequency generator 322 may be configured to generate a second high frequency power. The second matcher 324 may be connected between the second high frequency generator 322 and the upper electrode 124. The second matcher 324 may be used for impedance matching of the second high frequency power.

Referring back to FIG. 1, intensity of the plasma reaction of the reaction gas 210 may be proportional to a magnitude of the second high frequency power. By contrast, the first high frequency power may be used to concentrate or focus the reaction gas 210 on or near the substrate 10 and the ring member 130. Focusing intensity of the reaction gas 210 may be proportional to the first high frequency power. In other words, an etch rate of the substrate 10 may be proportional to the first high frequency power.

The plasma protection layer 500 may be provided on the ring member 130. The plasma protection layer 500 may be used to protect the ring member 130 against the reaction gas 210. In other words, the use of the plasma protection layer 500 may allow the ring member 130 to have an increased lifespan. Furthermore, the use of the plasma protection layer 500 may make it possible to prevent or suppress particles (not shown) from occurring.

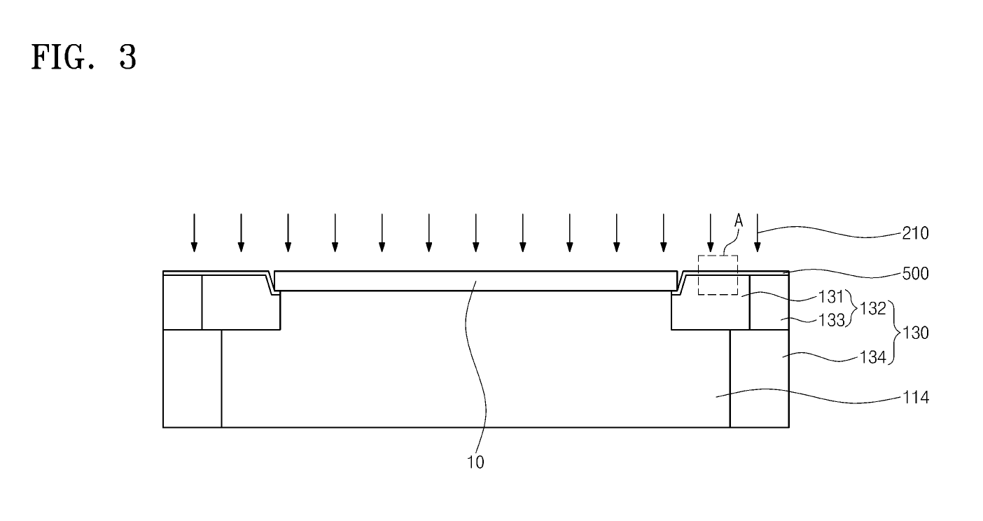

FIG. 3 is a sectional view illustrating a ring member 130 and a plasma protection layer 500 of FIG. 1 according to an exemplary embodiment.

Referring back to FIGS. 1 and 3, the substrate 10 and the ring member 130 may protect the electrostatic chuck 114 from the reaction gas 210. The ring member 130 may be used to fasten the substrate 10 on the electrostatic chuck 114. The ring member 130 may be formed of or include a material identical or similar to that of the substrate 10. For example, the ring member 130 may be formed of or include at least one of silicon (Si), silicon carbide (SiC), quartz, or ceramics. The ring member 130 may prevent an arcing phenomenon from occurring in the reaction gas 210, and thus, it is possible to control a defect distribution of the substrate 10. The ring member 130 may include, for example, an edge ring 132 and a ground ring 134. The edge ring 132 may be provided at the edge of the substrate 10. The edge ring 132 may be provided to cover an edge of the electrostatic chuck 114. The ground ring 134 may be provided to surround a sidewall of the electrostatic chuck 114. The ground ring 134 may be provided between the edge ring 132 and the wall liner 112. In an exemplary embodiment, the ring member 130 may further include other rings, in addition to the edge ring 132 and the ground ring 134.

The plasma protection layer 500 may be disposed on the edge ring 132. The plasma protection layer 500 may protect the edge ring 132 from the reaction gas 210. The edge ring 132 may include, for example, a focus ring 131 and a cover ring 133. The focus ring 131 may be provided near the edge of the substrate 10. The focus ring 131 may be provided to support the edge of the substrate 10. The focus ring 131 may be provided around the substrate 10 to have substantially the same top level as that of the substrate 10. The cover ring 133 may be provided around an edge of the focus ring 131. The cover ring 133 may enclose the edge of the focus ring 131. The plasma protection layer 500 may be coated on the focus ring 131. The focus ring 131 may be protected from the reaction gas 210 by the plasma protection layer 500. This arrangement of the plasma protection layer 500 and the focus ring 131 makes it possible for the focus ring 131 to have an increased lifespan. Alternatively, the plasma protection layer 500 may also be coated on the cover ring 133. In this case, the plasma protection layer 500 may protect the cover ring 133 from the reaction gas 210.

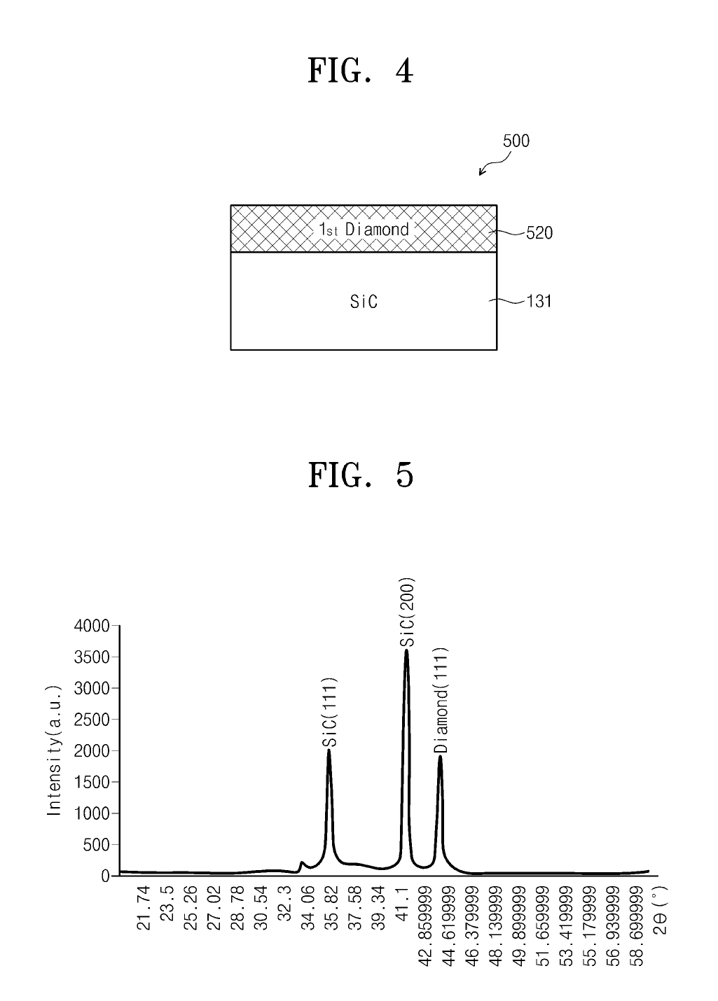

FIG. 4 is a sectional view illustrating an example of the focus ring 131 and the plasma protection layer 500 that are provided in the portion A of FIG. 3.

Referring to FIG. 4, the plasma protection layer 500 may be a carbon protection layer. For example, the plasma protection layer 500 may include a first diamond film 520. The first diamond film 520 may have a thickness ranging from about 10 μm to about 1000 μm. The focus ring 131 may include silicon carbide (SiC). Alternatively, the focus ring 131 may include silicon (Si), quartz, and ceramics.

FIG. 5 is a graph showing X-ray diffraction (XRD) curves of the focus ring 131 and the first diamond film 520 of FIG. 4. Here, the horizontal axis represents a 2θ angle and the vertical axis represents an intensity of XRD curve.

Referring back to FIGS. 4 and 5, the silicon carbide (SiC) of the focus ring 131 may have a (111) or (200) crystal plane. The (111) crystal plane may have a peak at the angle 2θ of about 35.8 degrees. The (200) crystal plane may have a peak at the angle 2θ of about 41.1 degrees. The first diamond film 520 may have the (111) crystal plane. The (111) crystal plane of the first diamond film 520 may have a peak at the angle 2θ of about 43.5 degrees.

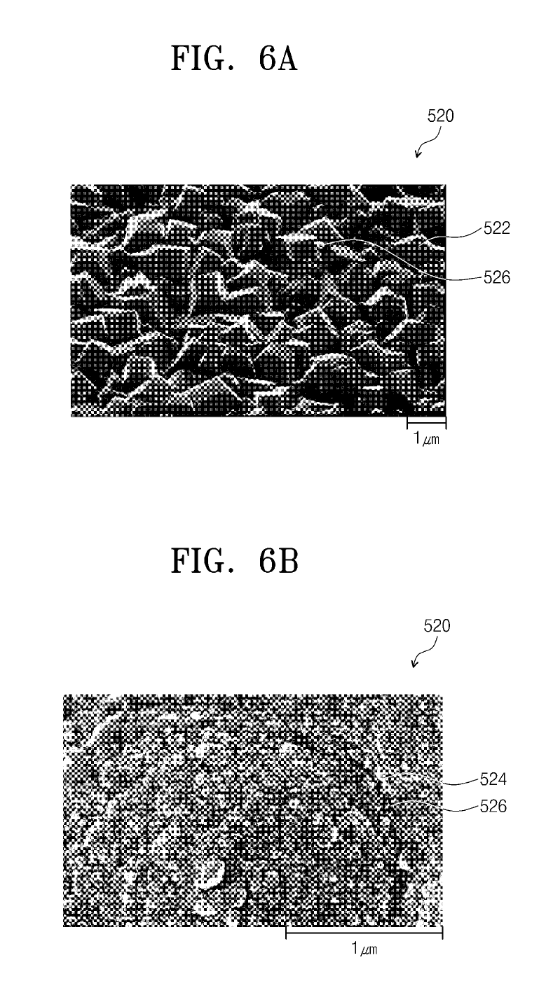

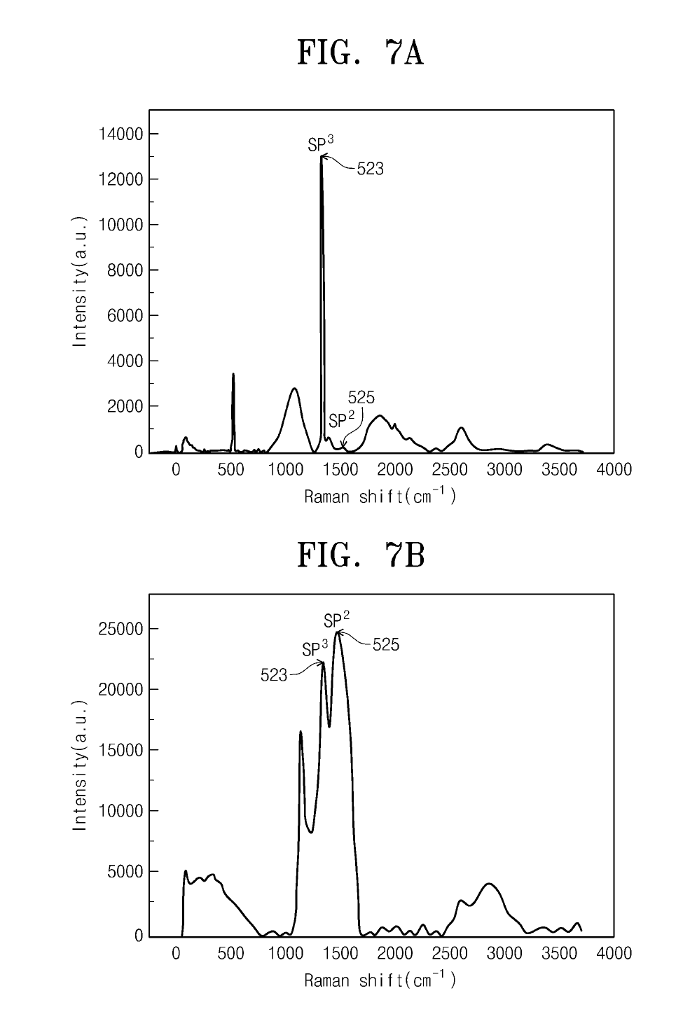

FIGS. 6A and 6B are plan views illustrating a first diamond film 520 of FIG. 4 according to an exemplary embodiment.

As shown in FIG. 6A, the first diamond film 520 was formed to include micro-crystalline diamonds (MCD) 522 and a graphite 526. The MCD 522 and the graphite 526 are mixed with each other, in the first diamond film 520. The MCD 522 has a size/diameter ranging from about 1 μm to about 15 μm. The graphite 526 has a size/diameter smaller than that of the MCD 522. For example, the graphite 526 had a diameter of 1 μm or smaller. A small amount of the graphite 526 is mixed in the MCD 522.

Referring to FIG. 6B, the first diamond film 520 includes nano-crystalline diamonds (NCD) 524 and the graphite 526. The NCD 524 was mixed with the graphite 526. The NCD 524 has a diameter ranging from about 10 nm to about 100 nm. The graphite 526 has substantially the same size as the NCD 524. However, the exemplary embodiment is not limited thereto. For example, the graphite 526 may have a size smaller than the NCD 524.

FIG. 7A is a graph illustrating an example of Raman spectrum of the micro-crystalline diamonds (MCD) 522 of FIG. 6A. Here, the horizontal axis represents a Raman shift and the vertical axis represents an intensity of Raman spectrum.

Referring to FIGS. 6A and 7A, the MCD 522 has a first peak 523 corresponding to SP³ hybridization bonding. The first peak 523 was detected as a Raman shift of about 1300 cm⁻¹. The SP³ hybridization bonding may correspond to a diamond bonding of carbon. The graphite 526 has a second peak 525 corresponding to SP² bonding. The SP² bonding was detected as a Raman shift of about 1500 cm⁻¹. The SP² bonding may correspond to a graphite bonding of carbon. The second peak 525 is much smaller than the first peak 523. The MCD 522 was much more than the graphite 526. In certain embodiments, the graphite 526 may hardly exist in the MCD 522.

FIG. 7B is a graph illustrating Raman spectrum of the nano-crystalline diamonds (NCD) 524 of FIG. 6B.

Referring to FIG. 7B, the NCD 524 has a first peak 523 corresponding to the SP³ hybridization bonding of carbon. Similarly, the graphite 526 has a second peak 525 corresponding to the SP² bonding of carbon. The SP³ hybridization bonding may correspond to the diamond bonding and the SP² bonding may correspond to the graphite bonding. In the exemplary embodiment, the first peak 523 is smaller than the second peak 525 in the case with NCD 524 and the graphite 526. The NCD 524 was mixed with the graphite 526.

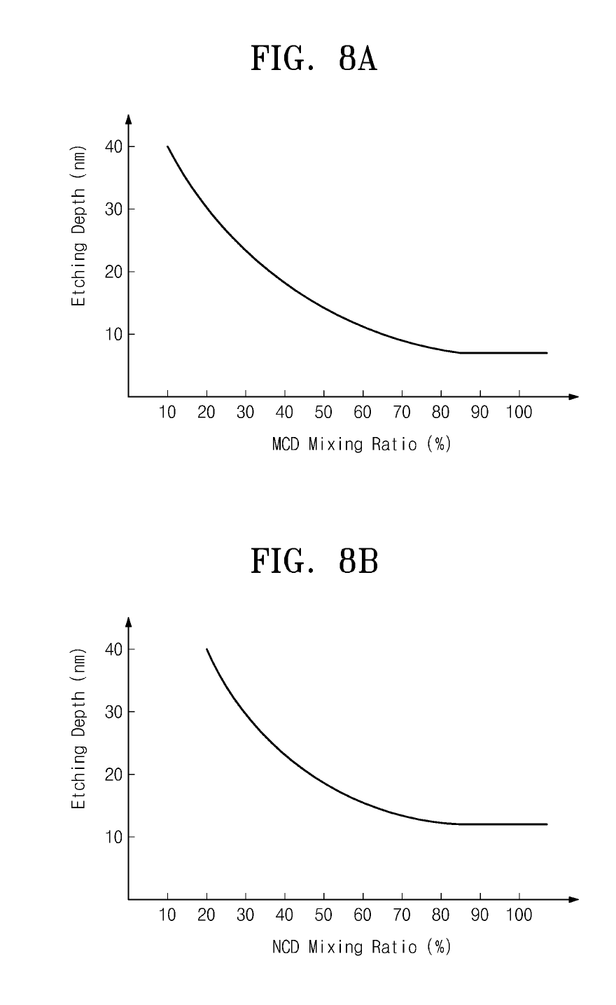

FIG. 8A is a graph showing an etching depth of the first diamond film 520 against a mixing ratio of the MCD 522 in the first diamond film 520 of FIG. 6A. Here, the horizontal axis represents an etching depth and the vertical axis represents a mixing ratio and/or volumetric ratio of the MCD 522.

Referring to FIG. 8A, the exemplary embodiment shows the higher a mixing ratio and/or volumetric ratio of the MCD 522 in the first diamond film 520, the lower the etching depth. For example, when the MCD 522 has a mixing ratio of 85% or higher, the etching depth was about 7 nm or less. The graphite 526 has a mixing ratio of 15% or lower. In the exemplary embodiment, the etching process may be performed with a first high frequency power of about 1 KW. The etch-resistant property improves when the MCD 522 has a mixing ratio of 85% or higher. When the MCD 522 had a mixing ratio from 85% to 100%, a diamond carbon film may be formed. When the MCD 522 had a mixing ratio from 20% to 85%, a diamond-like carbon (DLC) film may be formed. When the MCD 522 had a mixing ratio of 20% or less, a graphite carbon film may be formed.

FIG. 8B is a graph showing an etching depth of the diamond film 520 against a mixing ratio of the NCD 524 in the first diamond film of FIG. 6B. Here, the horizontal axis represents an etching depth and the vertical axis represents a mixing ratio of the NCD 524.

Referring to FIG. 8B, the exemplary embodiment according to FIG. 8 shows the higher a mixing ratio of the NCD 524, the lower the etching depth. For example, when the NCD 524 had a mixing ratio of 85% or higher, the etching depth is about 12 nm or less. In the exemplary embodiment, the graphite 526 has a mixing ratio of 15% or less. When the NCD 524 has a mixing ratio of 85% or higher, an etch-resistant property improves. When the NCD 524 has a mixing ratio from 85% to 100%, a diamond carbon film may be formed. When the NCD 524 has a mixing ratio from 20% to 85%, a diamond-like carbon (DLC) film may be formed. When the NCD 524 had a mixing ratio of 20% or less, a graphite carbon film may be formed.

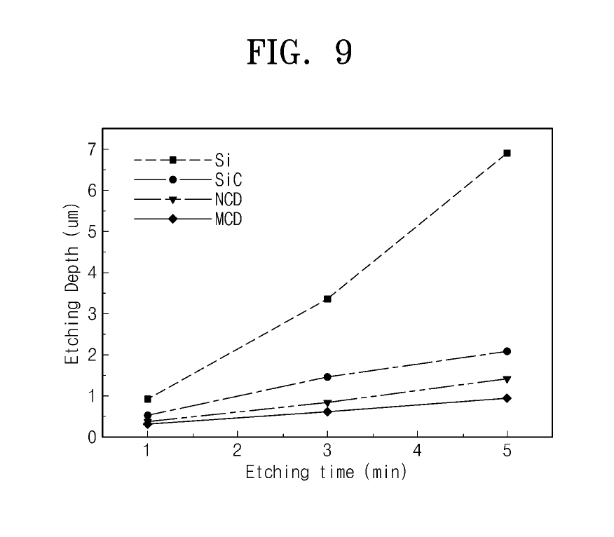

FIG. 9 is a graph showing the etch rate for each of the MCD 522, the NCD 524 (shown in FIGS. 6A and 6B), silicon (Si), and silicon carbide (SiC). Here, the horizontal axis represents an etching time and the vertical axis represents an etching depth.

Referring to FIG. 9, the MCD 522 and the NCD 524 are etched at etch rates slower than those of silicon (Si) and silicon carbide (SiC). The MCD 522 and the NCD 524 are etched at an etch rate of about ⅓ μm/min or less. By contrast, the silicon carbide (SiC) is etched at an etch rate of ⅓ μm/min or higher. Also, the silicon (Si) is etched at an etch rate of 1 μm/min or higher. That is, the MCD 522 and the NCD 524 has an etch-resistant property better than the silicon (Si) and the silicon carbide (SiC).

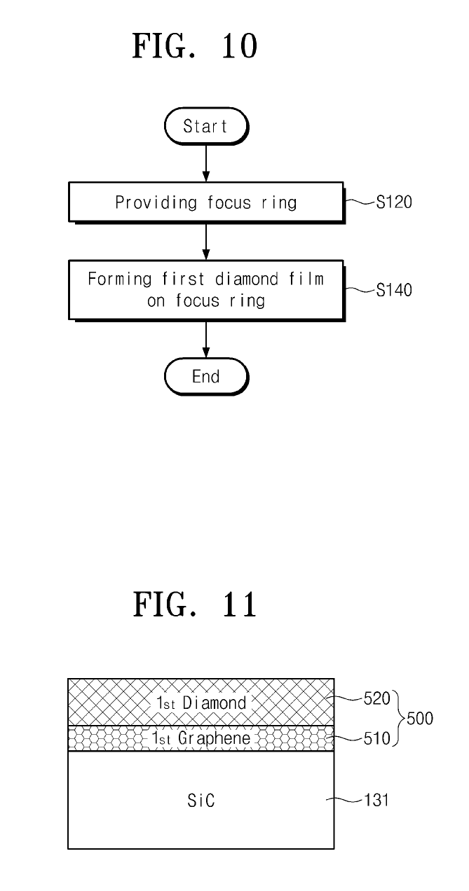

Hereinafter, a method of forming the plasma protection layer 500 of the substrate processing system 600 will be described with reference to FIGS. 10, 12, 14, and 16.

FIG. 10 is a flow chart illustrating a method of forming a plasma protection layer 500 of a substrate processing system 600 according to an exemplary embodiment.

Referring to FIGS. 4, 6A, 6B, and 10, the method of forming the plasma protection layer 500 may include steps of providing the focus ring 131 (in S120) and forming the first diamond film 520 (in S140).

In the exemplary embodiment, the step S120 of providing the focus ring 131 may include performing a texturing process on a surface of the focus ring 131. The surface texturing process may be performed to increase a surface roughness of the focus ring 131. For example, the step S120 of providing the focus ring 131 may include performing a dry etching process or a wet etching process on the focus ring 131. Alternatively, the step S120 of providing the focus ring 131 may include cleaning the focus ring 131. For example, the step S120 of providing the focus ring 131 may include a dry or wet cleaning step.

The step S140 of forming the first diamond film 520 may include a chemical vapor deposition process. For example, the first diamond film 520 may be formed using methane (CH4) gas at a temperature of about 800° C. or higher under a pressure from about 10K bar to 100K bar. Here, the pressure of 10K bar may be substantially equivalent to about 10,000 atm. An adhesive strength between the first diamond film 520 and the focus ring 131 may be proportional to the surface roughness of the focus ring 131.

FIG. 11 is a sectional view illustrating an example of the plasma protection layer 500 of FIG. 4.

Referring to FIG. 11, the plasma protection layer 500 may include a first graphene film 510 provided between the focus ring 131 and the first diamond film 520. The first graphene film 510 may have strength higher than the first diamond film 520. This is because the strength of the graphene is greater than two times that of the diamond. The first graphene film 510 may include a single graphene layer or a plurality of graphene layers. Accordingly, the use of the first graphene film 510 may make it possible to increase a lifespan of the focus ring 131.

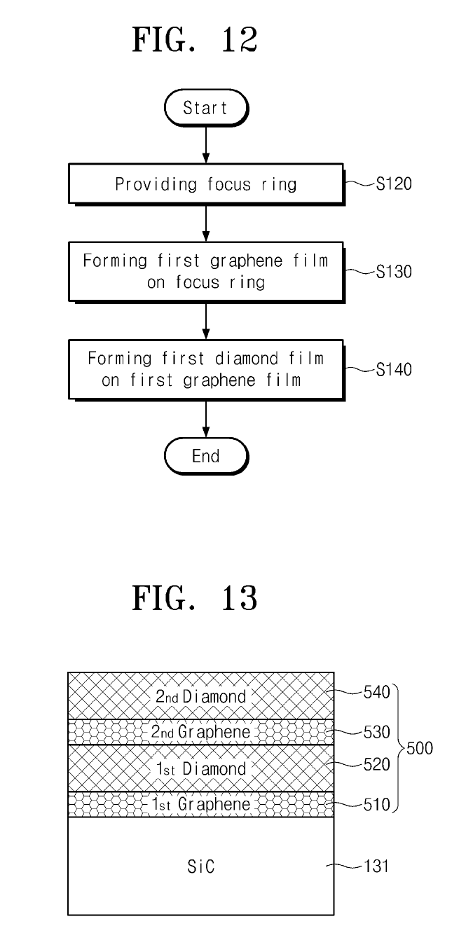

FIG. 12 is a flow chart illustrating a method of forming a plasma protection layer 500 of FIG. 11 according to an exemplary embodiment.

Referring to FIGS. 11 and 12, the method of forming the plasma protection layer 500 may include steps of providing the focus ring 131 (in S120), forming the first graphene film 510 (in S130), and forming the first diamond film 520 (in S140).

The steps S120 and S140 of providing the focus ring 131 and forming the first diamond film 520 may be performed in substantially the same manner as those of FIG. 10.

The step S130 of forming the first graphene film 510 may include a chemical vapor deposition process. The first graphene film 510 may be formed at a temperature higher than that for the first diamond film 520. For example, the first graphene film 510 may be formed using methane (CH₄) gas at a temperature of about 1500° C. or higher under a pressure of about 10-100K bar. The carbon elements contained in the silicon carbide (SiC) of the focus ring 131 may serve as a seed layer for forming the first graphene film 510.

The first diamond film 520 may be formed on the first graphene film 510 (in S140). The first diamond film 520 and the first graphene film 510 may be formed in an in-situ manner through a chemical vapor deposition process.

FIG. 13 is a sectional view illustrating a plasma protection layer 500 of FIG. 4 according to an exemplary embodiment.

Referring to FIG. 13, the plasma protection layer 500 may include a second graphene film 530 and a second diamond film 540 on the first diamond film 520.

The focus ring 131, the first graphene film 510, and the first diamond film 520 may be configured to have substantially the same features as those of FIG. 11.

The second graphene film 530 may have strength higher than the first diamond film 520. The second graphene film 530 may have the same strength as the first graphene film 510.

The second diamond film 540 may be provided on the second graphene film 530. The second diamond film 540 may have the same strength as the first diamond film 520. Although not shown, the second diamond film 540 may include at least one of the MCD or the NCD. The use of the second graphene film 530 and the second diamond film 540 may make it possible to increase a lifespan of the focus ring 131. In certain embodiments, at least one graphene film and/or at least one diamond film may be further provided on the second diamond film 540.

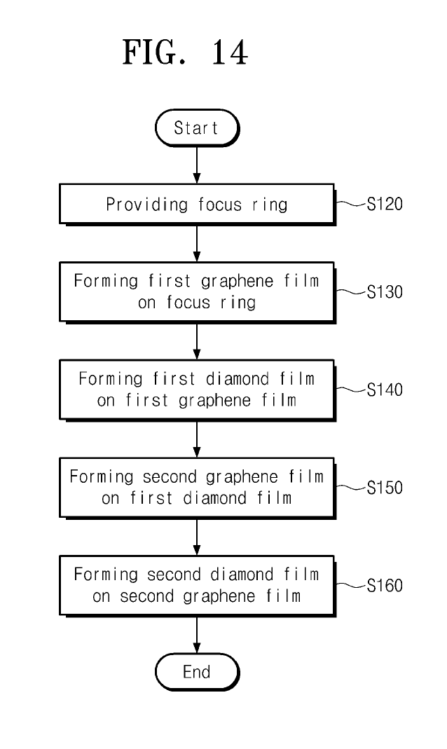

FIG. 14 is a flow chart illustrating a method of forming the plasma protection layer 500 of FIG. 13.

Referring to FIG. 14, the method of forming the plasma protection layer 500 may include steps of providing the focus ring 131 (in S120), forming the first graphene film 510 (in S130), forming the first diamond film 520 (in S140), forming the second graphene film 530 (in S150), and forming the second diamond film 540 (in S160).

The steps S120, S130, and S140 may be performed by substantially the same methods as those of FIG. 12.

Referring back to FIGS. 6A, 6B, and 14, the step S150 of forming the second graphene film 530 may include a chemical vapor deposition process. The second graphene film 530 may be formed at a temperature higher than that for the first diamond film 520. The second graphene film 530 may be formed using methane (CH₄) gas at a temperature of about 1500° C. or higher under a pressure of about 10-100K bar. The first diamond film 520 may be used as a seed layer for forming the second graphene film 530. The MCD 522, the NCD 524, or the graphite 526 of the first diamond film 520 may be used as a seed layer for forming the second graphene film 530.

The step S160 of forming the second diamond film 540 may include a chemical vapor deposition process. The second diamond film 540 may be formed at a temperature lower than that for the first graphene film 510 and the second graphene film 530. For example, the second diamond film 540 may be formed using methane (CH₄) gas at a temperature of about 800° C. or higher under a pressure of about 1-100K bar. The second diamond film 540 may be formed to have a thickness ranging from about 1 μm to about 100 μm. The first graphene film 510, the first diamond film 520, the second graphene film 530, and the second diamond film 540 may be formed in an in-situ manner through a chemical vapor deposition process.

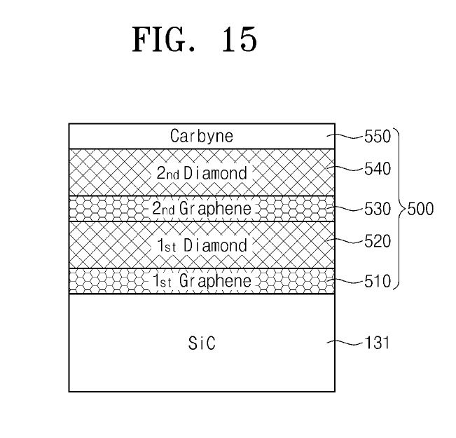

FIG. 15 is a sectional view illustrating an example of the plasma protection layer 500 of FIG. 4.

Referring to FIG. 15, the plasma protection layer 500 may include a carbyne film 550 on the second diamond film 540.

The first graphene film 510, the first diamond film 520, the second graphene film 530, and the second diamond film 540 may be configured to have substantially the same features as those of FIG. 13.

The carbyne film 550 may have hardness higher than the first graphene film 510, the first diamond film 520, the second graphene film 530, and the second diamond film 540. Hardness of the carbyne is about 3 times that of diamond and about 2 times that of graphene. Thus, the use of the carbyne film 550 may make it possible to increase a lifespan of the focus ring 131. In certain embodiments, at least one graphene film, at least one diamond film, and/or at least one carbyne film may be further provided on the carbyne film 550.

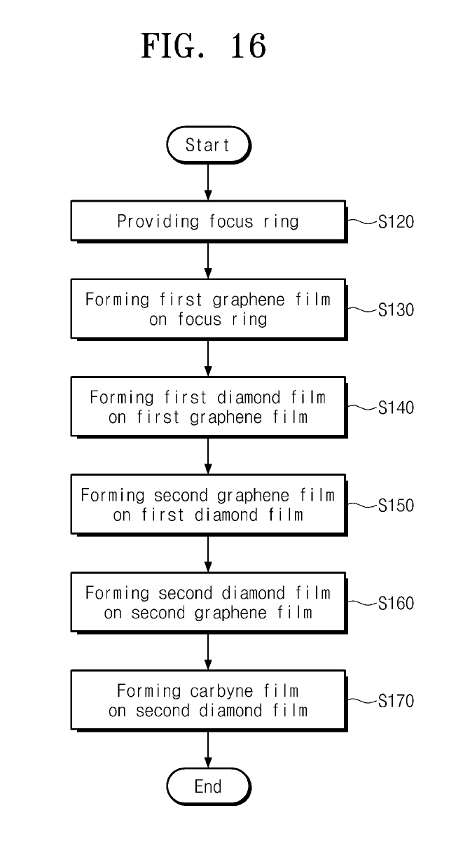

FIG. 16 is a flow chart illustrating a method of forming the plasma protection layer 500 of FIG. 15.

Referring to FIG. 16, he method of forming the plasma protection layer 500 may include steps of providing the focus ring 131 (in S120), forming the first graphene film 510 (in S130), forming the first diamond film 520 (in S140), forming the second graphene film 530 (in S150), forming the second diamond film 540 (in S160), and forming the carbyne film 550 (in S170).

The steps S120, S130, S140, S150, and S160 may be performed by substantially the same methods as those of FIG. 14.

The step S170 of forming the carbyne film 550 may include a chemical vapor deposition process. The carbyne film 550 may be formed under a pressure higher than pressures for the first graphene film 510, the first diamond film 520, the second graphene film 530, and the second diamond film 540. The carbyne film 550 may be formed using methane (CH₄) gas at a temperature of about 1500° C. or higher under a pressure of about 1000K bar or higher. The first graphene film 510, the first diamond film 520, the second graphene film 530, the second diamond film 540, and the carbyne film 550 may be formed in an in-situ manner through a chemical vapor deposition process.

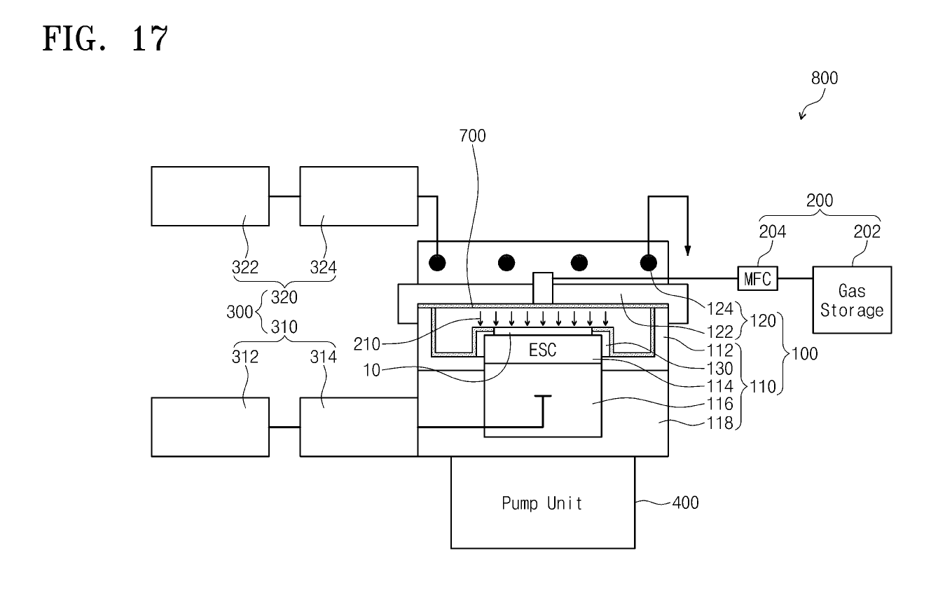

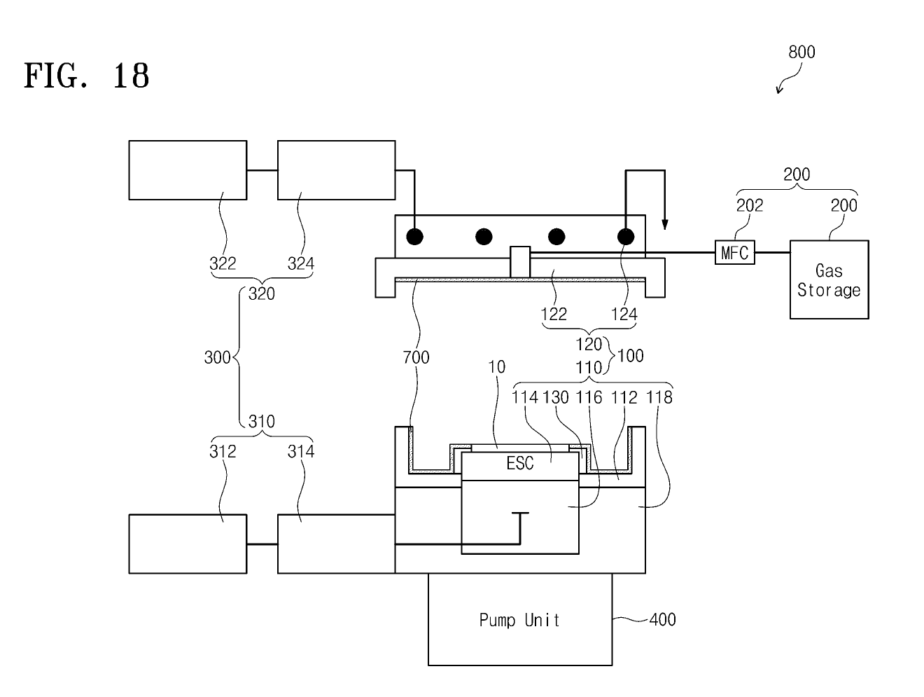

FIG. 17 is a sectional view illustrating a substrate processing system 800 according to an exemplary embodiment, and FIG. 18 is an exploded sectional view illustrating a chamber 100 of FIG. 17.

Referring to FIGS. 17 and 18, the substrate processing system 800 may include a plasma protection layer 700 on an inner surface of the chamber 100.

The chamber 100, the gas supplying unit 200, the high frequency power supply unit 300, and the pumping unit 400 may be configured to have substantially the same features as those of FIGS. 1 and 2.

The plasma protection layer 700 may be coated on the lower housing 110 and the upper housing 120. For example, the plasma protection layer 700 may be coated on the shower head 122. The plasma protection layer 700 may be coated on the wall liner 112 and the ring member 130. The plasma protection layer 700 may protect the shower head 122, the wall liner 112, and the ring member 130 from the reaction gas 210. This makes it possible for the shower head 122, the wall liner 112, and the ring member 130 to have increased lifespans, respectively.

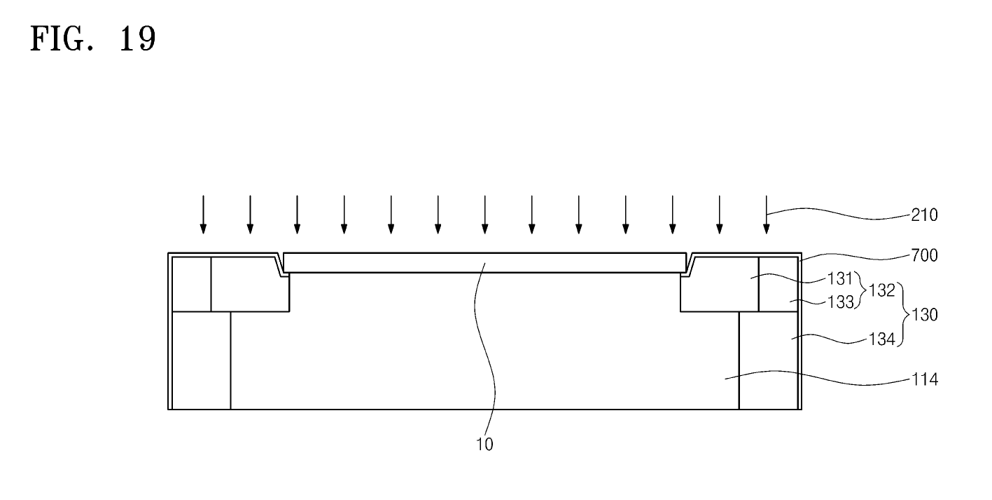

FIG. 19 is a sectional view illustrating the ring member 130 of FIG. 17 according to an exemplary embodiment.

Referring to FIG. 19, the plasma protection layer 700 may be coated on the focus ring 131, the cover ring 133, and the ground ring 134 of the ring member 130.

The electrostatic chuck 114 and the ring member 130 may be configured to have substantially the same features as those of FIG. 3.

The plasma protection layer 700 may be coated to cover an outer surface of the cover ring 133. The plasma protection layer 700 may also be coated to cover an outer surface of the ground ring 134. The plasma protection layer 700 may be provided to extend from the focus ring 131 to the ground ring 134. Accordingly, the plasma protection layer 700 may protect the focus ring 131, the cover ring 133, and the ground ring 134 from the reaction gas 210. Accordingly, it is possible to increase lifespans of the focus ring 131, the cover ring 133, and the ground ring 134.

According to exemplary embodiments of the inventive concept, a substrate processing system may include a carbon protection layer of diamond provided on a plasma processing module. The diamond has an etch-resistant property superior to other conventional materials, such as silicon, silicon carbide, and ceramics. Accordingly, the use of the carbon protection layer may make it possible to increase a lifespan of the plasma processing module. Furthermore, the carbon protection layer may suppress or prevent particles from occurring.

While exemplary embodiments of the inventive concepts have been particularly shown and described, it will be understood by one of ordinary skill in the art that variations in form and detail may be made therein without departing from the spirit and scope of the attached claims.

1. A substrate processing system, comprising:
a plasma processing module; and
a protection layer coated on the plasma processing module,
wherein the protection layer comprises a first diamond film.

2. The substrate processing system of claim 1, wherein the plasma processing module comprises:
an electrostatic chuck configured to fasten a substrate; and
an edge ring comprising:
a focus ring provided at an edge of the substrate; and
a cover ring enclosing the focus ring,
wherein the first diamond film is provided on the focus ring.

3. The substrate processing system of claim 2, wherein the focus ring comprises silicon carbide, and
wherein the first diamond film has a (111) crystal plane.

4. The substrate processing system of claim 1, wherein the first diamond film comprises:
micro-crystalline diamonds; or
nano-crystalline diamonds having a smaller size than a size of the micro-crystalline diamonds.

5. The substrate processing system of claim 4, wherein the first diamond film further comprises graphite that is mixed with the micro-crystalline diamonds or the nano-crystalline diamonds.

6. The substrate processing system of claim 5, wherein each of the micro- and nano-crystalline diamonds is provided to have a mixing ratio of 85% or higher in the first diamond film with respect to the graphite.

7. The substrate processing system of claim 1, wherein the protection layer further comprises a first graphene film disposed between the plasma processing module and the first diamond film.

8. The substrate processing system of claim 7, wherein the protection layer further comprises:
a second graphene film provided on the first diamond film; and
a second diamond film provided on the second graphene film.

9. The substrate processing system of claim 8, wherein the protection layer further comprises a carbyne film provided on the second diamond film.

10. The substrate processing system of claim 1, wherein the plasma processing module comprises a chamber, and
wherein the protection layer is coated on an inner surface of the chamber.

11-15. (canceled)

16. A substrate processing system, comprising:
an upper housing;
a lower housing below the upper housing; and
a protection layer coated on an inner surface of the lower housing,
wherein the protection layer comprises a first diamond film.

17. The substrate processing system of claim 16, wherein the lower housing comprises:
a wall liner;
an electrostatic chuck provided in the wall liner and configured to fasten a substrate; and
a first ring provided at an edge of the substrate, the first ring containing silicon carbide, wherein the first diamond film has a (111) crystal plane.

18. The substrate processing system of claim 17, wherein the protection layer further comprises a first graphene film provided on the first ring and the first diamond film.

19. The substrate processing system of claim 16, wherein the protection layer further comprises:
a second graphene film provided on the first diamond film; and
a second diamond film provided on the second graphene film.

20. The substrate processing system of claim 19, wherein the protection layer further comprises a carbyne film provided on the second diamond film.

21-32. (canceled)

33. A substrate processing apparatus, comprising:
a processing chamber configured to process a substrate using reaction gas; and
a protection layer configured to protect the processing chamber from the reaction gas supplied into the processing chamber,
wherein the protection layer comprises a first diamond film.

34. The substrate processing apparatus of claim 33, wherein the processing chamber comprises:
a lower housing; and
an upper housing detachably attached to the lower housing,
wherein the first diamond film is coated on an inner surface of the lower housing.

35. The substrate processing apparatus of claim 34, wherein the first diamond film is coated on an inner surface of the upper housing.

36. The substrate processing apparatus of claim 33, wherein the first diamond film comprises micro-crystalline diamonds (MCD) or nano-crystalline diamonds (NCD) and
wherein a particle size of the MCD is larger than a particle size of the NCD.

37. The substrate processing apparatus of claim 36, wherein the first diamond film further comprises graphite that is mixed with the MCD or the NCD.

38-41. (canceled)
